(19) United States
(12) Patent Application Publication
(10) Pub. No.: US 2012/0224438 A1
(43) Pub. Date: Sep. 6, 2012

(54) SEMICONDUCTOR MEMORY DEVICE

(75) Inventor: Satoshi INABA, Kanagawa (JP)

(73) Assignee: Kabushiki Kaisha Toshiba, Tokyo (JP)

(21) Appl. No.: 13/401,092

(22) Filed: Feb. 21, 2012

(30) Foreign Application Priority Data
Mar. 2, 2011 (JP) 2011-045000

(51) Int. Cl. G11C 7/00; H01L 29/772

(52) U.S. Cl. 365/189.011; 257/348; 257/E29.242

(57) ABSTRACT

According to one embodiment, a fin formed on a semiconductor substrate, a gate electrode provided on both sides of the fin via a gate dielectric film, a depletion layer that forms a potential barrier, which confines a hole in a body region between channel regions of the fin, in the fin, and a source/drain layer formed in the fin to sandwich the gate electrode are included.

### CROSS-REFERENCE TO RELATED APPLICATIONS

This application is based upon and claims the benefit of priority from Japanese Patent Application No. 2011-45000, filed on Mar. 2, 2011; the entire contents of which are incorporated herein by reference.

### FIELD

Embodiments described herein relate generally to a semiconductor memory device.

### BACKGROUND

Recently, information storage devices (memories) formed on a silicon substrate are widely used in current personal computers, home appliances, digital cameras, and mobile phones, and are increased in capacity and moreover reduced in price and improved in performance year by year.

Information storage devices are classified into some memory types depending on an information storage capacity, an access time, and the like, and 1-transistor type memories are studied and developed as one of memory device candidates that have a large capacity and are capable of high-speed operation equivalent to a dynamic memory (DRAM).

A 1-transistor type memory is called also a capacitor-less DRAM and functions as a memory by modulating an electrical potential of a channel portion in one field-effect transistor and generating a difference in an amount of read current. This is equivalent to varying a threshold voltage of a field-effect transistor by changing a potential of the channel portion.

Such a 1-transistor type memory includes one that uses a fin-type transistor formed on a bulk substrate. In this 1-transistor type memory, a potential barrier for holes is formed near the bottom of a fin and holes generated by GIDL (Gate Induced Drain Leakage current) are confined in the fin to change the potential of the channel portion. Therefore, in such a 1-transistor memory, it is important to make it difficult for holes confined in the fin to escape for holding data.

### BRIEF DESCRIPTION OF THE DRAWINGS

FIG. 1A is a perspective view illustrating a schematic configuration of a semiconductor memory device according to a first embodiment, FIG. 1B is a cross-sectional view of the semiconductor memory device in FIG. 1A cut along line A-A, and FIG. 1C is a diagram illustrating a P-type impurity concentration distribution and a potential distribution in a height direction of a fin 3 in FIG. 1B;

FIG. 2 is an equivalent circuit diagram of the semiconductor memory device shown in FIG. 1A;

FIG. 3A is a diagram illustrating a state of a depletion layer near a drain layer D when a band-to-band tunneling current is generated in the drain layer D in the semiconductor memory device in FIG. 1A, FIG. 3B is an energy band diagram near the drain layer D when a band-to-band tunneling current is generated in the semiconductor memory device in FIG. 1A;

FIG. 4 is a diagram illustrating a potential distribution in a depth direction in an inversion state when a substrate bias voltage is changed in the semiconductor memory device in FIG. 1A;

FIG. 5 is a diagram illustrating a potential distribution in a depth direction in an accumulation state when a substrate bias voltage is changed in the semiconductor memory device in FIG. 1A;

FIG. 6A is a timing chart illustrating one example of waveforms a gate voltage Vg, a drain voltage Vd, and a substrate bias voltage Vb in a write period, a hold period, and a read period at the time of writing of data “1” and FIG. 6B is a timing chart illustrating one example of waveforms of the gate voltage Vg, the drain voltage Vd, and the substrate bias voltage Vb in a write period, a hold period, and a read period at the time of writing of data “0”;

FIGS. 7A to 7E are cross-sectional views illustrating a manufacturing method of a semiconductor memory device according to a second embodiment;

FIG. 8 is a block diagram illustrating a schematic configuration of a semiconductor memory device according to a third embodiment; and

FIG. 9 is a plan view illustrating a layout of fins and gate electrodes of a semiconductor memory device according to a fourth embodiment.

### DETAILED DESCRIPTION

In general, according to a semiconductor memory device in embodiments, a fin, a gate electrode, a depletion layer, and a source/drain layer are provided. The fin is formed on a semiconductor substrate. The gate electrode is provided on both sides of the fin via a gate dielectric film. The depletion layer forms a potential barrier that confines a hole in a body region between channel regions of the fin. The source/drain layer is formed in the fin to sandwich the gate electrode.

A semiconductor memory device and a manufacturing method of a semiconductor memory device according to the embodiments will be explained below with reference to the drawings. The present invention is not limited to these embodiments.

### First Embodiment

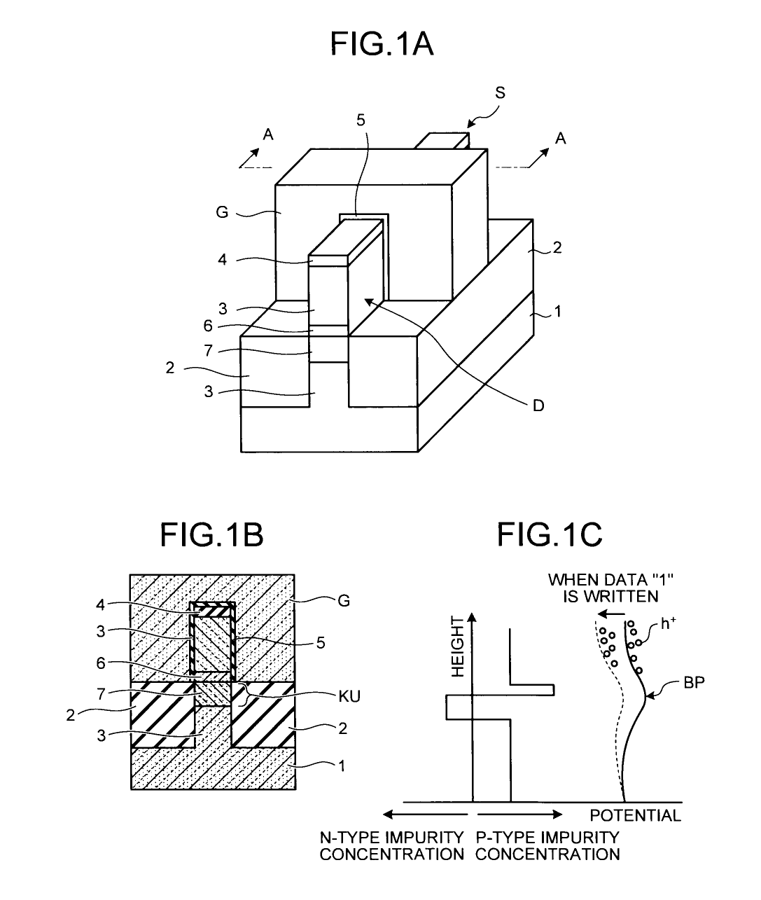

FIG. 1A is a perspective view illustrating a schematic configuration of a semiconductor memory device according to the first embodiment, FIG. 1B is a cross-sectional view of the semiconductor memory device in FIG. 1A cut along line A-A, and FIG. 1C is a diagram illustrating a P-type impurity concentration distribution and a potential distribution in a height direction of a fin 3 in FIG. 1B.

In FIG. 1A to FIG. 1C, the fin 3 is formed on a semiconductor substrate 1 and a cap layer 4 is formed on the fin 3. The material of the semiconductor substrate 1 can be selected, for example, from Si, Ge, SiGe, GaAs, InP, GaP, InGaAs, GaN, SiC, and the like. As the material of the cap layer 4, for example, a silicon nitride film can be used. Moreover, the conductivity type of the semiconductor substrate 1 and the fin 3 can be set to the P type. As this P-type impurity, for example, B can be used.

Then, a buried dielectric layer 2 is formed on the semiconductor substrate 1 to fill a portion between the fins 3. The height of the buried dielectric layer 2 can be set such that the upper portion of the fin 3 projects. Moreover, as the material of the buried dielectric layer 2, for example, a silicon oxide film can be used.

Then, gate electrodes G provided on both sides of the fin 3 via a gate dielectric film 5 are formed on the buried dielectric layer 2. The gate electrode G may be formed to span across the fin 3, that is, the gate electrodes G on both sides of the fin 3 may be integrated. As the material of the gate dielectric film 5, for example, a silicon oxide film can be used. As the material of the gate electrode G, for example, a polycrystalline silicon film can be used. Alternatively, as the material of the gate electrode G, for example, metallic compounds, such as titanium nitride, tantalum carbon, a lanthanum-based material, an aluminum-based material, and a magnesium-based material may be used alone or in combination.

In the present embodiment, because an n-type fin FET is used, a P-type impurity diffusion layer 6 and an N-type impurity diffusion layer 7 are provided at a position around the middle between the tip end and the bottom of the fin 3. Then, a depletion layer KU is formed in the interface between the P-type impurity diffusion layer 6 and the N-type impurity diffusion layer 7 by forming the PN junction with the P-type impurity diffusion layer 6 and the N-type impurity diffusion layer 7, so that a potential barrier BP that confines holes h+ in the body region between the channel regions of the fin 3 can be formed in the fin 3. As the P-type impurity of the P-type impurity diffusion layer 6, for example, B or In can be used. As the N-type impurity of the N-type impurity diffusion layer 7, for example, P or As can be used. The P-type impurity concentration of the P-type impurity diffusion layer 6 is set to be higher than the P-type impurity concentration of the fin 3. Moreover, the N-type impurity concentration of the N-type impurity diffusion layer 7 is set to be lower than the P-type impurity concentration of the P-type impurity diffusion layer 6, so that the depletion layer KU is configured to extend on the N-type impurity diffusion layer 7 side. The N-type impurity diffusion layer 7 is preferably fully depleted by a built-in potential.

The N-type impurity diffusion layer 7 is preferably arranged so as not to overlap the channel region formed in the fin 3 in the gate electrode G. Moreover, preferably, the N-type impurity diffusion layer 7 is formed at a position to be sandwiched on both sides by the buried dielectric layer 2 and does not protrude outside the fin 3.

Moreover, in the fin 3, a drain layer D and a source layer S are formed to sandwich the channel region formed in the fin 3 in the gate electrode G. The N-type impurity diffusion layer 7 needs to be electrically separated from the drain layer D and the source layer S via the depletion layer KU. The conductivity type of the drain layer D and the source layer S can be set to the N-type. As this N-type impurity, for example, P or As can be used.

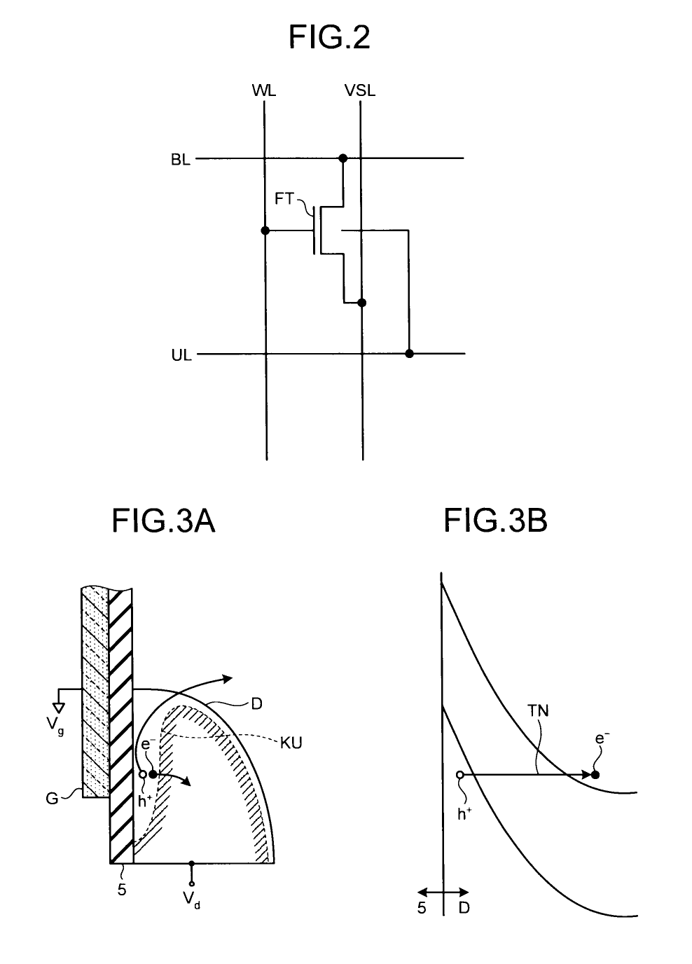

FIG. 2 is an equivalent circuit diagram of the semiconductor memory device shown in FIG. 1A.

In FIG. 2, the gate electrode G, the drain layer D, and the source layer S in FIG. 1A form a fin transistor FT. The gate electrode G is connected to a word line WL, the drain layer D is connected to a bit line BL, the source layer S is connected to a source line SL, and the semiconductor substrate 1 is connected to a substrate bias line UL. A gate voltage Vg can be applied to the word line WL, a drain voltage Vd can be applied to the bit line BL, a source voltage Vs can be applied to the source line SL, and a substrate bias voltage Vb can be applied to the substrate bias line UL.

The operation of the semiconductor memory device in FIG. 1A is explained below. In the following explanation, a state in which holes are confined in the body region between the channel regions of the fin 3 is set as a state in which data ‘1’ is written and a state in which holes in the body region are drained is set as a state in which data ‘0’ is written.

When the data ‘1’ is written in this semiconductor memory device, the gate voltage Vg is set to a negative potential, the drain voltage Vd is set to a positive potential, and the substrate bias voltage Vb and the source voltage Vs are set to a ground potential.

At this time, when the gate voltage Vg is set to a negative potential, the fin transistor FT is turned off and the depletion layer near the drain layer D is bent and intense electric field is applied, so that a band-to-band tunneling current flows. This band-to-band tunneling current generates GIDL.

FIG. 3A is a diagram illustrating a state of the depletion layer near the drain layer D when a band-to-band tunneling current is generated in the semiconductor memory device in FIG. 1A and FIG. 3B is an energy band diagram near the drain layer D when a band-to-band tunneling current is generated in the semiconductor memory device in FIG. 1A.

In FIG. 3A, when the gate voltage Vg is set to a negative potential and the drain voltage Vd is set to a positive potential, the depletion layer KU near the drain layer D is bent and intense electric field is applied. Therefore, as shown in FIG. 3B, a band-to-band tunneling current TN flows in the depletion layer KU and pairs of holes h+ and electrons e− are generated. Among them, the holes h+ are confined in the body region between the channel regions of the fin 3 by the potential barrier BP and the data ‘1’ is written by GIDL.

On the other hand, when the data ‘0’ is written in this semiconductor memory device, the gate voltage Vg, the substrate bias voltage Vb, and the source voltage Vs are set to a ground potential and the drain voltage Vd is set to a negative potential. Therefore, holes accumulated in the body region between the channel regions of the fin 3 are drained to the drain layer D and the data ‘0’ is written.

When holes h+ are confined in the body region between the channel regions of the fin 3, the potential of the body region becomes high on the plus side compared with the case where holes h+ are not confined. Therefore, when holes h+ are confined in the body region between the channel regions of the fin 3, the gate voltage Vg (threshold Vt) at which the fin transistor FT starts to move into an on-state becomes low compared with the case where holes h+ are not confined and an amount of current that flows when the same gate voltage Vg is applied becomes large. It is possible to determine whether data stored in the semiconductor memory device in FIG. 1A is ‘0’ or ‘1’ by detecting the difference in this amount of current.

In a method of writing the data ‘1’ by GIDL, the gate voltage Vg is set to a negative potential, so that, as shown in FIG. 10, the potential with respect to holes h+ in the channel region is lowered. Therefore, it is possible to make it difficult for holes h+ to escape to the semiconductor substrate 1 side, so that the write efficiency can be improved.

Moreover, the depletion layer KU is formed between a portion near the height of the upper end portion of the ST1 and the root of the fin 3, so that, even when the depletion layer KU is electrically separated from the semiconductor substrate 1 in the fin 3, the potential barrier BP can be made high. Therefore, holes h+ can be efficiently confined in the body region between the channel regions of the fin 3 and a contact for applying voltage to the N-type impurity diffusion layer 7 is not needed, so that the layout area can be reduced.

Moreover, the N-type impurity diffusion layer 7 is arranged so as not to overlap the channel region, so that the depletion layer KU can be suppressed from affecting the threshold, the gate capacity, a S factor, and the like of the fin transistor FT. Therefore, it is possible to prevent device design from becoming difficult and the position and the thickness of the depletion layer KU do not need to be controlled accurately, so that a manufacturing process can be generalized.

Moreover, a gate current Ig and a drain current Id in an accumulation state of the field-effect transistor can be represented by the following Equation (1) and Equation (2).

Ig(L,Vg,Vb)=Igch(L,Vg,Vb)+Igs+Igd (1)

Id(L,Vg,Vb)=Igd+IGIDL(Vg,Vb)+IJL (2)

In Equation (1), Igs+Igd is a gate leakage current generated in a portion in which the gate electrode G and the source layer S and the drain layer D overlap. Moreover, Igch is a gate leakage current generated between the channel region and the gate electrode G, and is typically a function of a gate length L, the gate voltage Vg, and the substrate bias voltage Vb.

In Equation (2), a component monitored as the drain current Id is a gate leakage current Igd, a junction leakage current IJL, and IGIDL (Vg,Vb) generated by GIDL.

This band-to-band tunneling current TN depends on the width and the electric field of the depletion layer KU and therefore is affected by an impurity profile of the drain layer D. If the impurity concentration of the drain layer D is too large, the depletion layer KU is not bent by the gate voltage Vg, and if the impurity concentration of the drain layer D is too low, the width of the depletion layer KU becomes large and it becomes difficult to cause band-to-band tunneling. Therefore, GIDL when the gate voltage Vg is fixed can be increased by adjusting the impurity profile of the drain layer D and near the channel region near the drain layer D.

Moreover, the fin transistor FT is a double-gate transistor. Therefore, the short channel effect and characteristic variation attributed to a substrate impurity profile can be suppressed, so that the transistor is suitable for scaling of a memory.

Moreover, because the fin transistor FT operates as a fully-depleted channel device, the Vt (threshold) characteristics do not vary even if the substrate bias voltage Vb is applied. Specially, the fin transistor FT using a bulk substrate does not include a box layer, so that when the substrate bias voltage Vb is applied, the substrate bias voltage Vb can be directly transmitted to the fin 3. However, the Id-Vg characteristics in a gate voltage range in an inversion region (state in which an inversion layer of a minority carrier is formed in a channel region) from a depletion region in a fully-depleted state are substantially determined by a work function of the shape (fin width) of the fin 3 and the gate electrode G.

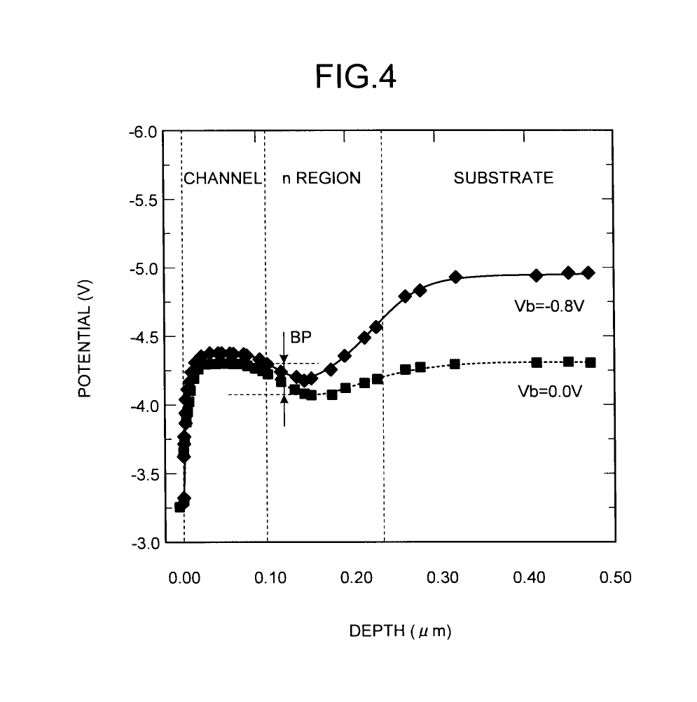

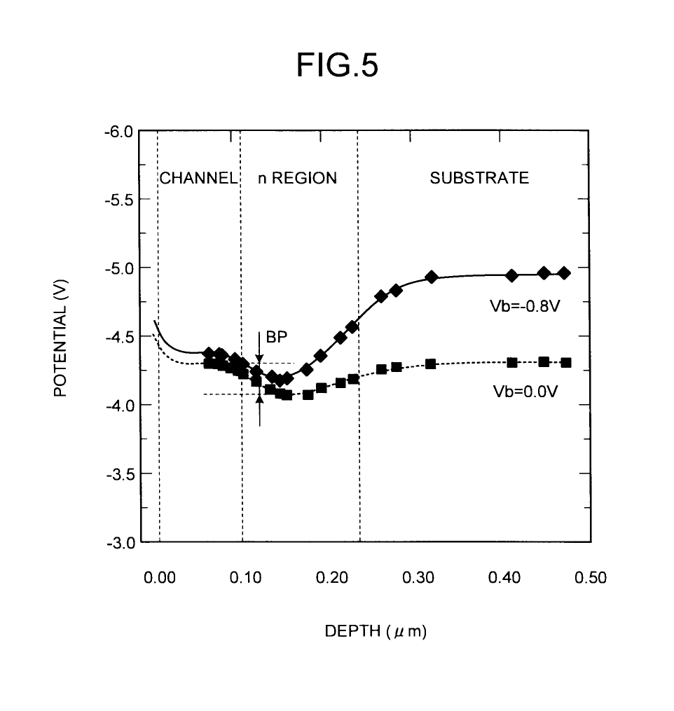

FIG. 4 is a diagram illustrating a potential distribution in a depth direction in an inversion state when the substrate bias voltage is changed in the semiconductor memory device in FIG. 1A and FIG. 5 is a diagram illustrating a potential distribution in a depth direction in an accumulation state when the substrate bias voltage is changed in the semiconductor memory device in FIG. 1A.

In FIG. 4, when a PNP junction is provided in the fin 3 and the depletion layer KU is formed, the potential barrier BP of about 0.25 to 0.3 V is generated even in an inversion state.

Moreover, the potential barrier BP formed in the depletion layer KU is substantially independent on the substrate bias voltage Vb. In other words, even if the potential of the semiconductor substrate 1 changes, the potential variation is absorbed in the n region. Therefore, even if the potential of the semiconductor substrate 1 varies for some reasons (noise or soft error by α-ray), the height of the potential barrier BP with respect to holes h+ and the potential in the channel region vary little, so that a device having a high resistance to variation can be realized.

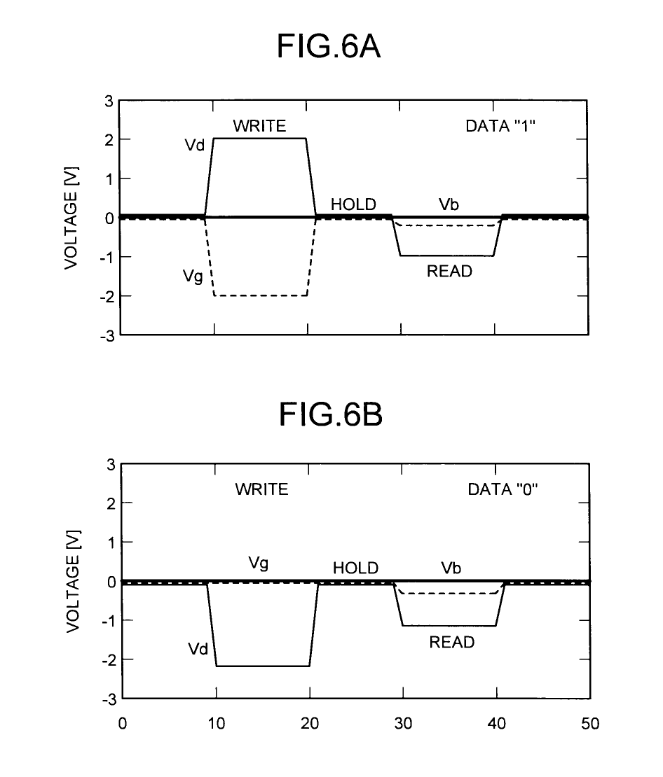

FIG. 6A is a timing chart illustrating one example of waveforms of the gate voltage Vg, the drain voltage Vd, and the substrate bias voltage Vb in a write period, a hold period, and a read period at the time of writing of the data “1” and FIG. 6B is a timing chart illustrating one example of waveforms of the gate voltage Vg, the drain voltage Vd, and the substrate bias voltage Vb in a write period, a hold period, and a read period at the time of writing of the data “0”.

In FIG. 6A, in the write period of the data ‘1’, for example, the gate voltage Vg is set to −2 V, the drain voltage Vd is set to 2 V, and the substrate bias voltage Vb and the source voltage Vs are set to 0 V.

At this time, holes h+ generated by GIDL are confined in the body region between the channel regions of the fin 3 by the potential barrier BP, so that the data ‘1’ is written.

In the hold period after writing the data ‘1’, for example, the gate voltage Vg, the drain voltage Vd, the substrate bias voltage Vb, and the source voltage Vs are set to 0 V.

At this time, holes h+ generated by GIDL remain confined in the body region between the channel regions of the fin 3 by the potential barrier BP.

In the read period after holding the data ‘1’, for example, the gate voltage Vg is set to −0.05 V, the drain voltage Vd is set to −1 V, and the source voltage Vs and the substrate bias voltage Vb are set to 0 V.

At this time, when holes h+ are confined in the body region between the channel regions of the fin 3, the threshold Vt becomes low and an amount of current of the fin transistor FT becomes large compared with the case where holes h+ are not confined.

On the other hand, in FIG. 6B, in the write period of the data ‘0’, for example, the gate voltage Vg, the substrate bias voltage Vb, and the source voltage Vs are set to 0 V, and the drain voltage Vd is set to −2 V.

At this time, holes h+ accumulated in the body region between the channel regions of the fin 3 are drained to the drain later D, so that the data ‘0’ is written.

In the hold period after writing the data ‘0’, for example, the gate voltage Vg, the drain voltage Vd, the substrate bias voltage Vb, and the source voltage Vs are set to 0 V.

At this time, holes h+ remain drained from the body region between the channel regions of the fin 3.

In the read period after holding the data ‘0’, for example, the gate voltage Vg is set to −0.05 V, the drain voltage Vd is set to −1 V, and the substrate bias voltage Vb and the source voltage Vs are set to 0 V.

At this time, when holes h+ are not confined in the body region between the channel regions of the fin 3, the threshold Vt becomes high and an amount of current of the fin transistor FT becomes small compared with the case where holes h+ are confined.

In the above embodiment, the method of forming the fin 3 directly from the semiconductor substrate 1 is explained, however, a well may be formed in the semiconductor substrate 1 and the fin 3 may be formed from this well. In this case, it is sufficient to apply a well bias voltage to the well instead of the substrate bias voltage Vb.

### Second Embodiment

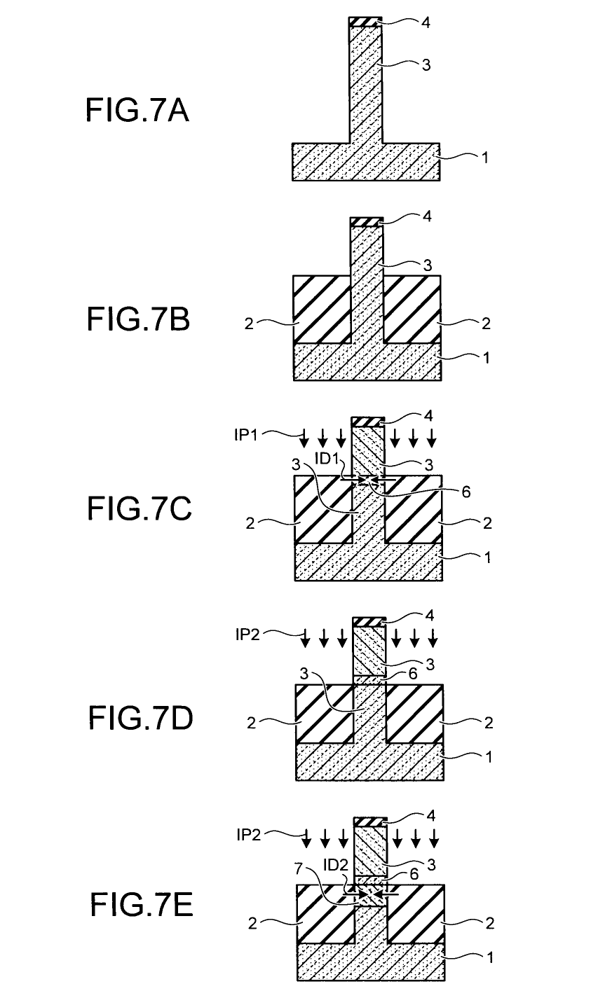

FIGS. 7A to 7E are cross-sectional views illustrating a manufacturing method of a semiconductor memory device according to the second embodiment.

In FIG. 7A, after forming the cap layer 4 on the semiconductor substrate 1 by a method such as CVD, the semiconductor substrate 1 is processed by using a photolithography technology and an anisotropic etching technology to form the fin 3 on the semiconductor substrate 1.

Next, as shown in FIG. 7B, the buried dielectric layer 2 is formed on the semiconductor substrate 1 to fill a portion between the fins 3, by a method such as CVD. Then, the buried dielectric layer 2 is etched back to thin the buried dielectric layer 2, thereby causing the tip end portion of the fin 3 to project above the buried dielectric layer 2.

Next, as shown in FIG. 7C, a P-type impurity such as In is injected by ion implantation IP1 vertically to the buried dielectric layer 2. At this time, large-angle scattering ID1 of the vertically-injected P-type impurity ions occurs with a fixed probability in the surface layer of the buried dielectric layer 2 to cause the P-type impurity ions to enter the fin 3, thereby forming the P-type impurity diffusion layer 6, which is arranged near the surface layer of the buried dielectric layer 2, in the fin 3.

Next, as shown in FIG. 7D, the buried dielectric layer 2 is further etched back to further thin the buried dielectric layer 2. At this time, the position of the surface of the buried dielectric layer 2 preferably matches the position of the lower surface of the P-type impurity diffusion layer 6.

Next, as shown in FIG. 7E, an N-type impurity such as As is injected by ion implantation IP2 vertically to the buried dielectric layer 2. At this time, large-angle scattering ID2 of the vertically-injected N-type impurity ions occurs with a fixed probability in the surface layer of the buried dielectric layer 2 to cause the N-type impurity ions to enter the fin 3, thereby forming the N-type impurity diffusion layer 7, which is arranged near the surface layer of the buried dielectric layer 2, in the fin 3. Consequently, the PNP junction is formed in the fin 3 and the depletion layer KU is formed in the fin 3. At this time, adjacent fin transistors FT can be electrically separated by forming this PNP junction between the tip end and the root of the fin 3 so as not to reach the semiconductor substrate 1.

Thereafter, as shown in FIG. 1B, after forming the gate dielectric film 5 on the side surface of the fin 3, the gate electrode G is formed to sandwich the fin 3.

### Third Embodiment

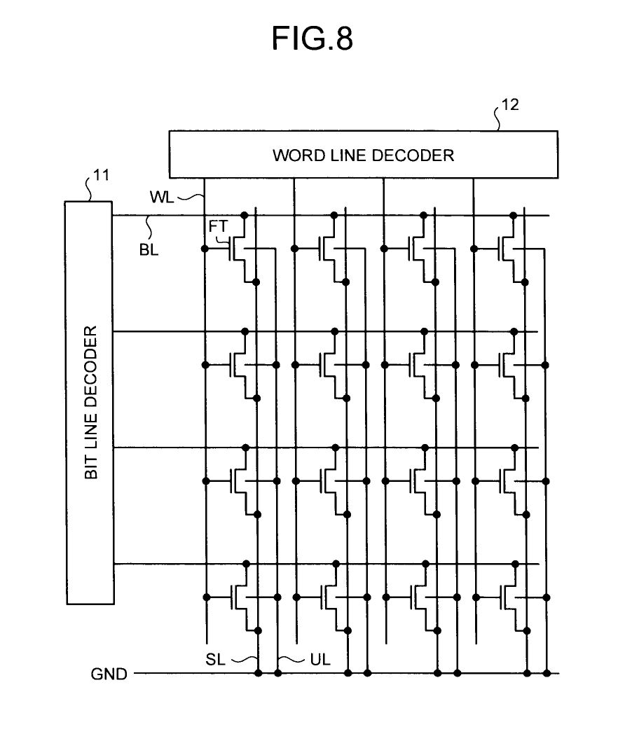

FIG. 8 is a block diagram illustrating a schematic configuration of a semiconductor memory device according to the third embodiment. FIG. 8 illustrates the case of three rows and three columns.

In FIG. 8, in this semiconductor memory device, the fin transistors FT are arranged in a matrix manner in a row direction and a column direction. The word line WL is connected to a word line decoder 12, the bit line BL is connected to a bit line decoder 11, and the substrate bias line UL and the source line SL are connected to a ground potential GND.

The bit line decoder 11 can apply the drain voltage Vd to the bit line BL of a selected row. The word line decoder 12 can apply the gate voltage Vg to the word line WL of a selected column.

Then, the gate voltage Vg is applied to the gate electrode G of a selected cell, which is selected in the bit line decoder 11 and the word line decoder 12, via the word line WL and the drain voltage Vd is applied to the drain layer D via the bit line BL, so that the write operation and the read operation are performed.

### Fourth Embodiment

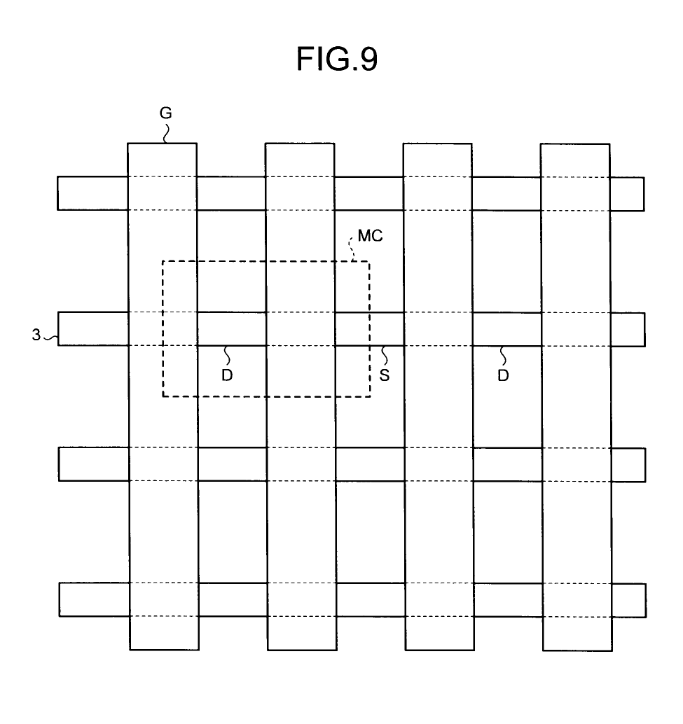

FIG. 9 is a plan view illustrating a layout of the fins and the gate electrodes of a semiconductor memory device according to the fourth embodiment. FIG. 9 illustrates the case of four rows and four columns.

In FIG. 9, a plurality of the fins 3 is formed in parallel in a row direction on the semiconductor substrate 1. Moreover, a plurality of the gate electrodes G is formed in parallel in a column direction to intersect with the fins 3. In the fin 3, the drain layer D and the source layer S are formed to sandwich the channel region formed in the fin 3 in the gate electrode G. The drain layer D and the source layer S are shared between adjacent fin transistors FT on the same fin 3.

A contact to be connected to the N-type impurity diffusion layer 7 does not need to be formed individually for each fin transistor FT by depleting the N-type impurity diffusion layer 7 in FIG. 1A, so that an area of a memory cell MC can be made small. For example, when the width and the interval of the gate electrodes G are defined as F, because the drain layer D and the source layer S can be shared by adjacent fin transistors FT, the area of the memory cell MC can be 2F×3F=6F², that is, the area can be made equal to or less than a DRAM of 6F² to 8F². On the other hand, if a contact to be connected to the N-type impurity diffusion layer 7 is formed individually for each fin transistor FT, the area of the memory cell MC becomes 2F×5F=10F², that is, the area becomes larger than a DRAM of 6F² to 8F².

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a fin formed on a semiconductor substrate;
a gate electrode provided on both sides of the fin via a gate dielectric film;
a depletion layer that forms a potential barrier in the fin, the potential barrier confining a hole in a body region between channel regions of the fin; and
a source/drain layer formed in the fin to sandwich the gate electrode.

2. The semiconductor memory device according to claim 1, further comprising:
a first-conductivity-type impurity diffusion layer formed in the fin; and
a second-conductivity-type impurity diffusion layer in which the depletion layer is formed by being bonded to the first-conductivity-type impurity diffusion layer.

3. The semiconductor memory device according to claim 2, wherein the second-conductivity-type impurity diffusion layer is fully depleted by a built-in potential.

4. The semiconductor memory device according to claim 3, further comprising a buried dielectric layer that is buried between fins and separates the second-conductivity-type impurity diffusion layer between the fins.

5. The semiconductor memory device according to claim 4, wherein a position of a boundary of the first-conductivity-type impurity diffusion layer and the second-conductivity-type impurity diffusion layer corresponds to a position of a surface of the buried dielectric layer.

6. The semiconductor memory device according to claim 5, wherein a position of a lower end of the gate electrode corresponds to the position of the boundary of the first-conductivity-type impurity diffusion layer and the second-conductivity-type impurity diffusion layer.

7. The semiconductor memory device according to claim 2, wherein the second-conductivity-type impurity diffusion layer is electrically separated from the source/drain layer via the depletion layer.

8. The semiconductor memory device according to claim 2, wherein data “1” is written by confining a hole generated by GIDL in the fin.

9. The semiconductor memory device according to claim 8, wherein data “0” is written by draining a hole confined in the fin.

10. The semiconductor memory device according to claim 1, wherein
a plurality of the fins is formed in parallel in a row direction,
a plurality of the gate electrodes is formed in parallel in a column direction to intersect with the fins, and
a drain layer or a source layer is formed in the fin between the gate electrodes.

11. A semiconductor memory device comprising:
a well formed in a semiconductor substrate;
a fin formed on the well;
a gate electrode provided on both sides of the fin via a gate dielectric film;
a depletion layer that forms a potential barrier in the fin, the potential barrier confining a hole in a body region between channel regions of the fin; and
a source/drain layer formed in the fin to sandwich the gate electrode.

12. The semiconductor memory device according to claim 11, further comprising:
a first-conductivity-type impurity diffusion layer formed in the fin; and
a second-conductivity-type impurity diffusion layer in which the depletion layer is formed by being bonded to the first-conductivity-type impurity diffusion layer.

13. The semiconductor memory device according to claim 12, wherein the second-conductivity-type impurity diffusion layer is fully depleted by a built-in potential.

14. The semiconductor memory device according to claim 13, further comprising a buried dielectric layer that is buried between fins and separates the second-conductivity-type impurity diffusion layer between the fins.

15. The semiconductor memory device according to claim 14, wherein a position of a boundary of the first-conductivity-type impurity diffusion layer and the second-conductivity-type impurity diffusion layer corresponds to a position of a surface of the buried dielectric layer.

16. The semiconductor memory device according to claim 15, wherein a position of a lower end of the gate electrode corresponds to the position of the boundary of the first-conductivity-type impurity diffusion layer and the second-conductivity-type impurity diffusion layer.

17. The semiconductor memory device according to claim 12, wherein the second-conductivity-type impurity diffusion layer is electrically separated from the source/drain layer via the depletion layer.

18. The semiconductor memory device according to claim 12, wherein data “1” is written by confining a hole generated by GIDL in the fin.

19. The semiconductor memory device according to claim 18, wherein data “0” is written by draining a hole confined in the fin.

20. The semiconductor memory device according to claim 11, wherein
a plurality of the fins is formed in parallel in a row direction,
a plurality of the gate electrodes is formed in parallel in a column direction to intersect with the fins, and
a drain layer or a source layer is formed in the fin between the gate electrodes.
